(19) United States
(12) Patent Application Publication
(10) Pub. No.: US 2026/0252778 A1
(43) Pub. Date: Aug. 27, 2026

(54) System and Method of Automatically Cataloging and Searching 2D Material Subflakes for Automatic Stacking in Accordance with a Stack Design Paradigm

(71) Applicant: Brookhaven Science Associates, LLC, Upton, NY (US)

(72) Inventors: Yutao Li, Brookhven, NY (US); Huandong Chen, Coram, NY (US); Kazuhiro Fujita, Stony rook, NY (US)

(21) Appl. No.: 19/549,366

(22) Filed: Feb. 25, 2026

Related U.S. Application Data
(60) Provisional application No. 63/763,313, filed on Feb. 26, 2025.

(51) Int. Cl. G06F 30/392; G06F 16/538; G06F 16/583

(52) U.S. Cl. CPC G06F 30/392; G06F 16/538; G06F 16/583

(57) ABSTRACT

System and method of stacking two-dimensional (2D) crystal materials, including: receiving a stack design paradigm specifying a spatial relationship between at least two selected 2D crystal materials, a thickness parameter for each of the 2D crystal materials, and a core area for each of the 2D crystal materials; searching a flake database for images of subflakes related to the selected 2D crystal materials that meet the thickness and the core area for each of the 2D materials; generating a recommendation of a heterogeneous stack of images of the subflakes according to the spatial relationship, overlapping core areas of the subflakes; and presenting the heterogenous stack.

### CROSS-REFERENCE TO RELATED APPLICATIONS

This application claims the benefit of priority to U.S. Provisional Patent Application Ser. No. 63/763,313, filed Feb. 26, 2025, the entire content of which is incorporated herein for all purposes. U.S. patent application Ser. No. ______, Attorney Docket No. 369-322, filed on Feb. 25, 2026, and entitled Method and Apparatus for Automatic Stacking of 2D Material Flakes, is incorporated herein by reference in its entirety.

### STATEMENT OF GOVERNMENT RIGHTS

The present application was made with government support under contract number DE-SC0012704 awarded by the United States Department of Energy. The United States government has certain rights in the invention(s).

### BACKGROUND

### Field

The present application relates to staking two-dimensional materials. More specifically, the present application is directed to a system and method of system and method capable of automatically cataloging and searching 2D material subflakes for automatically stacking the subflakes according to a stack design paradigm.

### Brief Discussion of Related Art

Two-dimensional (2D) material devices can leverage ultrathin, atomic-layer materials like graphene, hexagonal boron nitride (hBN), transition metal dichalcogenides-TMDs (e.g. MoS₂,WSe₂), molybdenum disulfide (MoS₂), as well as other 2D materials to create different electronic devices. In particular, when various 2D material layers are vertically stacked as a van der Waals heterostructure (hereinafter “heterostructure” or “stack”), they can allow for different types of functionalities. For example, such a heterostructure can include graphene as an electronic layer for high-speed electronics and flexible conductors, and hBN as a dielectric layer to separate the graphene electronic layer.

A 2D material is frequently produced by exfoliating one or more flakes (e.g., typically a monolayer or several layers) from a bulk-layered crystal structure. Such exfoliation is often called a “scotch-tape” method, involving use of adhesive tape to peel off thin layer(s) from the bulk crystal. The resulting 2D material flakes are then transferred to a substrate, such as a wafer of SiO₂/Si (hereinafter “wafer”), for electronic device fabrication.

Certain 2D materials, such as graphene and hBN, exhibit a wide range of exotic physical properties. They can be stacked in a heterostructure, in a LEGO-like fashion. Almost all electronic devices that include 2D materials involve a stack of more than two layers of 2D materials. Despite their promises, 2D material-based electronic devices have not been commercialized.

One of the main roadblocks is a sheer amount of human labor that is involved in making a high-quality 2D material heterostructure or stack. The stacking process is a highly specialized skill that takes years to fully master, and it can take days if not weeks of human labor to fabricate a 2D material stack with clean interlayer interfaces. In particular, flakes can include not only different outside dimensions but different thicknesses within the same flake and can be exfoliated in various positional relationships on the wafer, often impeding flake selection and stacking that satisfy design requirements for a 2D material heterostructure.

There is currently no automated process capable of scanning flakes exfoliated on a wafer to determine subflakes of a flake having various thicknesses, dimensions, and locations. Moreover, there is provided no automated process that is capable of searching subflakes to satisfy design requirements for a 2D material heterostructure.

It is therefore desirable to provide a robust system and method capable of automatically cataloging and searching 2D material subflakes for automatically stacking the subflakes according to a stack design paradigm.

### SUMMARY

There is described a system and method capable of automatically cataloging and searching 2D material subflakes for automatically stacking the subflakes according to a stack design paradigm.

In accordance with an embodiment, there is disclosed a system to stack two-dimensional (2D) crystal materials, wherein the system includes a processing device and a memory storing instructions that, when executed by the processing device, perform the following operations. The operations of the system include: receiving a stack design paradigm specifying a spatial relationship between at least two selected 2D crystal materials, a thickness parameter for each of the 2D crystal materials, and a core area for each of the 2D crystal materials; searching a flake database for images of subflakes related to the selected 2D crystal materials that meet the thickness and the core area for each of the 2D materials; generating a recommendation of a heterogeneous stack of images of the subflakes according to the spatial relationship, overlapping core areas of the subflakes; and presenting the heterogenous stack.

In some cases, the operations of the system can include instructing a scanning and stacking transfer device to physically generate the heterogenous stack by retrieving and stacking the subflakes of the images, exfoliated on a wafer according to the stack design paradigm.

In some cases, the operations of the system can include determining an inner dimension (ID1) of a first subflake and an outer dimension (OD2) of a second subflake, such that OD2⊂ID1.

In some cases, the operations of the system can include determining an inner dimension (ID1) of a first subflake, an outer dimension (OD2) of a second subflake, and an inner dimension (ID3) of a third flake, such that OD2⊂ID1 and OD2⊂ID3.

In some cases, the operations of the system can include determining an inner dimension (ID1) of a first subflake, an inner dimension (ID2) and outer dimension (OD2) of a second subflake, and an inner dimension (ID3) and an outer dimension (OD3) of a third flake, such that OD2⊂ID1 and ID2 [symbol] OD3 and ID2∩ID3≠∅.

In some cases, the at least two selected 2D crystal materials include at least boron nitride, and graphene or graphite. In some cases, the boron nitride is a hexagonal boron nitride (hBN).

In some cases, the operations of the system cam include generating a record in the flake database for each of the subflakes.

The operations of generating a record in the flake database for each of the subflakes can include: scanning a plurality images of flakes exfoliated at locations of a wafer; generating an edge image for each of the flakes; determining an outer dimension (OD) of each of the flakes; identifying one or more subflakes of each the flakes; determining an inner dimension (ID) of each of the subflakes; computing an average thickness of each of the subflakes; and saving a record including a subflake identifier, a flake identifier, location of the flake exfoliated on the wafer, OD of the flake, ID of the subflake, and the average thickness of the subflake.

The operations of generating a record in the flake database for each of the subflakes can further include determining an average background image for at least a portion of the wafer using several random images of the plurality of images scanned from the wafer; de-vignetting the plurality images based on the average background image; and generating the edge image for each of the flakes based on one of look-up table transformations coupled with canny edge detection, or k-clustering.

In accordance with another embodiment, there is disclosed a method of stacking two-dimensional (2D) crystal materials, wherein the method includes the following operations. The operations of the method include: receiving a stack design paradigm specifying a spatial relationship between at least two selected 2D crystal materials, a thickness parameter for each of the 2D crystal materials, and a core area for each of the 2D crystal materials; searching a flake database for images of subflakes related to the selected 2D crystal materials that meet the thickness and the core area for each of the 2D materials; generating a recommendation of a heterogeneous stack of images of the subflakes according to the spatial relationship, overlapping core areas of the subflakes; and presenting the heterogenous stack.

In some cases, the operations of the method can include instructing a scanning and stacking transfer device to physically generate the heterogenous stack by retrieving and stacking the subflakes of the images, exfoliated on a wafer according to the stack design paradigm.

In some cases, the operations of the method can include determining an inner dimension (ID1) of a first subflake and an outer dimension (OD2) of a second subflake, such that OD2⊂ID1.

In some cases, the operations of the method can include determining an inner dimension (ID1) of a first subflake, an outer dimension (OD2) of a second subflake, and an inner dimension (ID3) of a third flake, such that OD2⊂ID1 and OD2⊂ID3.

In some cases, the operations of the method can include determining an inner dimension (ID1) of a first subflake, an inner dimension (ID2) and outer dimension (OD2) of a second subflake, and an inner dimension (ID3) and an outer dimension (OD3) of a third flake, such that OD2⊂ID1 and ID2 [symbol] OD3 and ID2∩ID3≠∅.

In some cases, the at least two selected 2D crystal materials include at least boron nitride, and graphene or graphite. In some cases, the boron nitride is a hexagonal boron nitride (hBN).

In some cases, the operations of the method can include generating a record in the flake database for each of the subflakes.

The operations of generating a record in the flake database for each of the subflakes can include: scanning a plurality images of flakes exfoliated at locations of a wafer; generating an edge image for each of the flakes; determining an outer dimension (OD) of each of the flakes; identifying one or more subflakes of each of the flakes; determining an inner dimension (ID) of each of the subflakes; computing an average thickness of each of the subflakes; and saving a record including a subflake identifier, a flake identifier, location of the flake exfoliated on the wafer, OD of the flake, ID of the subflake, and the average thickness of the subflake.

The operations of generating a record in the flake database for each of the subflakes can further include determining an average background image for at least a portion of the wafer using several random images of the plurality of images scanned from the wafer; de-vignetting the plurality images based on the average background image; and generating the edge image for each of the flakes based on one of look-up table transformations coupled with canny edge detection, or k-clustering.

These and other purposes, goals, and advantages of the present application will become apparent from the following detailed description of example embodiments read in connection with the accompanying drawings.

### BRIEF DESCRIPTION OF THE DRAWINGS

Some embodiments are illustrated by way of example and not limitation in the figures of the accompanying drawings in which:

FIG. 1A illustrates a block diagram of an example system to automatically scan, catalog, and search 2D material flakes and subflakes for automatic stacking according to a stack design paradigm;

FIG. 1B illustrates an example material scanning and stacking transfer device illustrated in FIG. 1;

FIGS. 2A and 2B illustrate example graphical user interfaces generated by the material scanning and computing device illustrated in FIG. 1, to automatically scan, catalog, and search 2D material subflakes for automatic stacking according to a stack design paradigm;

FIG. 3 illustrates an example wafer that includes an example multiplicity of flakes for scanning, cataloging, and stacking using the system illustrated in FIG. 1;

FIGS. 4-7B graphically illustrate example scanning of the wafer illustrated in FIG. 3 to generate a multiplicity of original images saved to the flake database illustrated in FIG. 1, and further processing of the original images to identify flakes and/or subflakes of the flakes in the original images as illustrated in FIG. 7A for storage as records in a flake database illustrated in FIGS. 1 and 7B;

FIGS. 8A and 8B illustrate an alternative example embodiment of generating an example final edge image based on a de-vignetted image using k-means clustering, in contrast to generating the example final edge image according to LUT transformations and canny edge detection as illustrated in FIG. 6;

FIG. 9 is a flowchart of an example method for scanning and analyzing a wafer illustrated in FIG. 3 that includes a multiplicity of exfoliated 2D material flakes;

FIGS. 10A and 10B illustrate example graphical user interfaces generated by the material scanning and computing device illustrated in FIG. 1, to automatically scan, catalog, and search 2D material subflakes for automatic stacking according to a stack design paradigm;

FIGS. 11A-11C illustrate several example stack design paradigms for stacking flakes and/or subflakes.

FIGS. 12A and 12B illustrate example flakes and/or subflakes selected from the flake database illustrated in FIG. 1, based on a selected stack design paradigm and a plurality of selected parameters related to the flakes and/or subflakes;

FIG. 13 illustrates an example automated stacking recommendation image that overlays two flake images that are found in the flake database as illustrated in FIG. 1, based on a required stack design paradigm, as well as thicknesses and core area parameters;

FIG. 14 is an example is a flowchart of an example method of generating a stack recommendation of flakes resulting from a search of the flake database 108 illustrated in FIG. 1, and stacking a heterogeneous stack of 2D materials from the wafer illustrated in FIG. 3 that includes a multiplicity of exfoliated 2D material flakes, according to a stack design paradigm and parameters associated with the 2D materials; and

FIG. 15 illustrates a block diagram of an example general computer system capable of performing any methods or computer-based functions in accordance with FIGS. 1-14.

### DETAILED DESCRIPTION

Described herein are a system and a method directed to of system and method capable of cataloging and searching 2D material subflakes for automatically stacking the subflakes according to a stack design paradigm. In the following description, for the purposes of explanation, numerous specific details are set forth in order to provide a thorough understanding of example embodiments or aspects. It will be evident, however, to one skilled in the art, that an example embodiment may be practiced without all of the disclosed specific details.

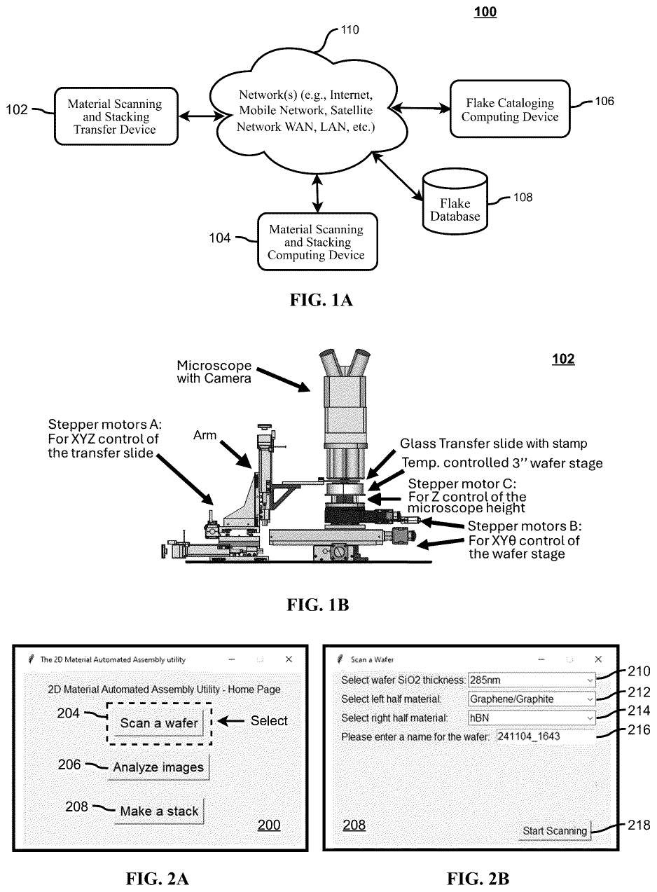

FIG. 1A illustrates a block diagram of an example system 100 to automatically scan, catalog, and search 2D material flakes and subflakes for automatic stacking according to a stack design paradigm. The example system 100 includes a material scanning and transfer device 102, a material scanning and stacking computing device 104, a subflake cataloging computing device 106, a flake database 108, and a network 110 connecting the foregoing system components 102-108.

The material scanning and transfer device 102 is configured to receive a SiO₂/Si wafer (e.g., 3″ wafter) having a multiplicity of 2D material flakes—a plurality of which might include two or subflakes in each flake—deposited thereon, and to scan the wafer in order to take images of the wafer. In particular, an image can be taken approximately every 628 μm×447 μm and approximately 13,000 images can cover the entire wafer. Each scanned image is associated with a pair of coordinates (e.g., x, y coordinates) representing a location on the wafer from which the image (e.g., 628 μm×447 μm) is taken, wherein the coordinate location can be used as part of the image's filename.

2D materials also known as 2D atomic crystals are characterized by having atomic-level thickness that is typically a single atom or a few atoms thick and a planar honeycomb lattice structure. Because of their layered, sheet-like structure, these 2D materials are often referred to as layered materials or van der Waals materials, as their layers when stacked are held together by weak van der Waals forces.

As the wafer is scanned, the resulting multiplicity of images is transmitted to the material scanning and stacking computing device 104 for storing, analyzing, and cataloging, which will be described in greater detail hereinafter with reference to FIGS. 3-9. The wafer is thus scanned until the entirety of the wafer or a desired portion of the wafer is scanned (e.g., half of wafer could be desired to be scanned). At this stage it is simply important to note that the catalog of subflakes and their associated images will be stored in the flake database 108, for use in automatically generating a stack recommendation and automatically stacking a heterogeneous structure or stack of subflakes according to a stack design paradigm.

Moreover, the material scanning and transfer device 102 is configured to receive from the material scanning and transfer device 104, a selection of various 2D material subflakes that were exfoliated on a wafer (e.g., identified and cataloged as described herein) and a stack design paradigm, and further configured to automatically generate a heterogeneous structure of the subflakes by transferring the subflakes from the wafer into a stack according to the stack design paradigm.

The material scanning and stacking computing device 104 is configured to instruct the material scanning and transfer device 102 to scan the wafer, generating a multiplicity of images of the wafer (e.g., each image representing approximately a 628 μm×447 μm of the wafer), wherein the material scanning and stacking computing device 104 is configured to store the images in the flake database 108 (e.g., each image filename can include an x-y location of the wafer from which the image was obtained). The scanning is described in greater detail hereinbelow with refence to FIG. 3.

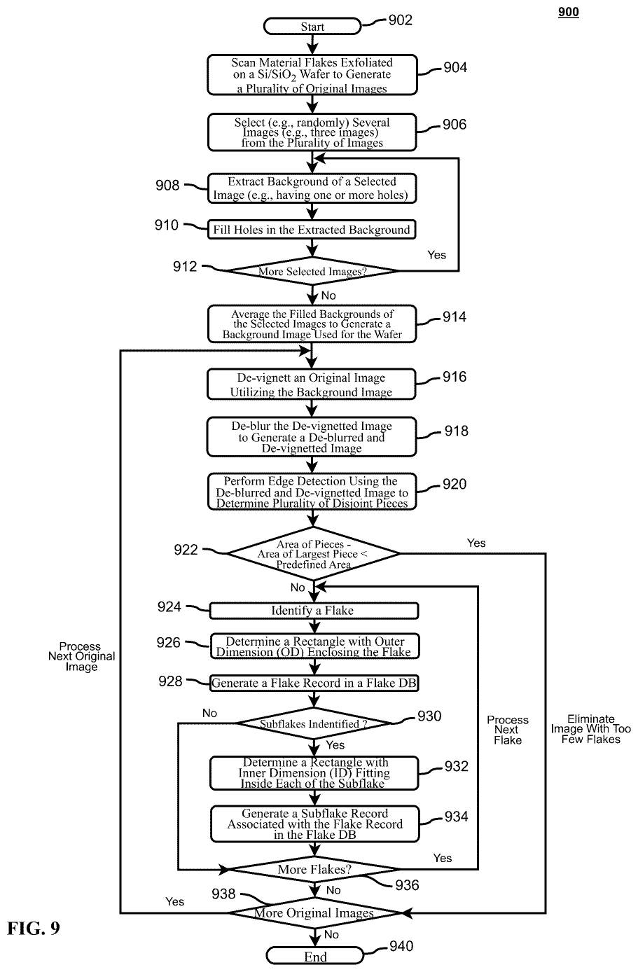

Moreover, the material scanning and stacking computing device 104 is configured to analyze the obtained images and catalog the subflakes in the images as records that are generated in the flake database 108 (e.g., each record can include an x-y location of the flake in the image, which can be a displacement from a location at which the image was taken on the wafer), or to offload such analyzing and cataloging to the subflake cataloging computing device 106, which would then generate the records in the flake database 108. The analyzing and cataloging of the subflakes in the multiplicity of images is described in greater detail hereinbelow with refence to FIG. 9.

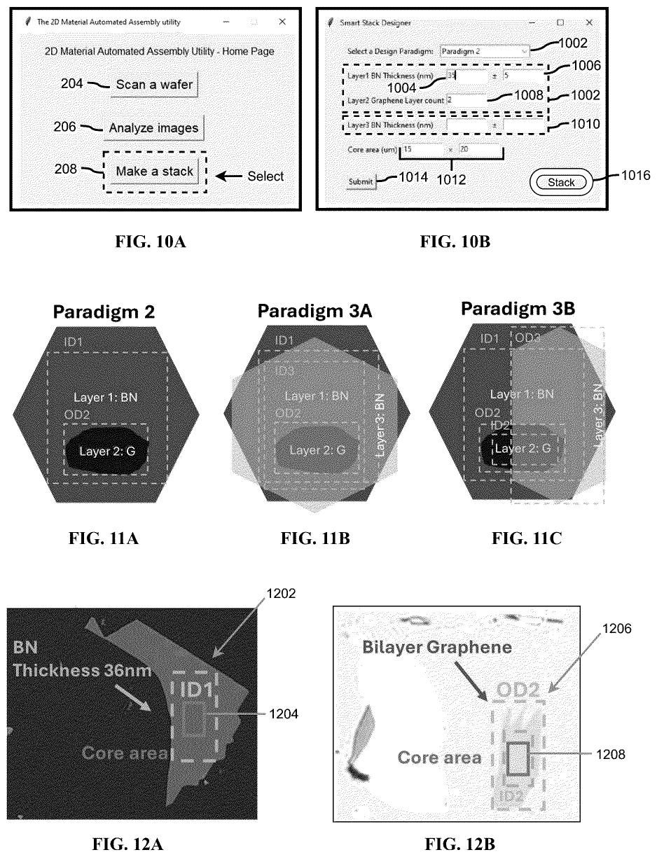

Lastly, the material scanning and stacking computing device 104 is configured to automatically generate a stacking recommendation based on user-requested parameters for the 2D materials (e.g., at least a thickness of each 2D material and an overlap core area of the materials), and further to automatically instruct the material scanning and transfer device 102 to stack a heterogenous structure or stack of subflakes obtained from the wafer, based on a user-selected stack design paradigm and user-selected parameters, as will be described in greater detail hereinbelow with reference to FIGS. 10A-14.

The subflake cataloging computing device 106 is configured to access a multiplicity of scanned images from the flake database 108, and to automatically process the images so as to catalog the subflakes in association with the relevant flakes as records in the flake database 108.

The flake database 108 is configured to store a scanned multiplicity of images from a certain wafer and a flake database of subflakes. Sample records in the flake database 108 will be described hereinafter in greater detail with reference to FIG. 7. It should be noted that multiple wafers can be scanned, with related images and generated records cataloged in similar fashion for storage in the database 108.

The network 110 can include Internet, mobile network(s), satellite network(s), WiFi, WAN, LAN, a combination thereof, etc. The foregoing system components 102-108 can be or can be part of computing devices (e.g., computers, servers, databases, mobile device, etc.) capable of connecting to and communicating over the network 110. The computing devices can be connected via wireless and/or wired configurations and/or interfaces via one or more of the Internet, mobile network(s), satellite network(s), WiFi, WAN, LAN, etc., using conventional or yet to be developed communication standards.

FIG. 1B illustrates an example material scanning and stacking transfer device 102 as illustrated in FIG. 1. The material scanning and transfer device 102 includes a microscope and camera for scanning a wafer disposed on a wafer stage and thus obtaining scanned images of flakes/subflakes exfoliated on the wafer, as well an arm with a transfer slide for picking and stacking certain selected flakes/subflakes according to a stack design paradigm. Additionally, the material scanning and stacking transfer device 102 includes certain electronics for communicating with the material scanning and stacking computing device 104, in relation to scanning the wafer and stacking a heterogenous stack according to the stack design paradigm.

Manual as well as motorized devices, including various step motors, are used to control the material scanning and transfer device 102 for adjusting alignment the wafer stage (wafer) in relation to the microscope/camera for scanning, and for adjusting alignment of the arm and the transfer slide in relation to the wafer stage (wafer) to pick up flakes/subflakes for stacking.

Stepper motors A are configured to control x, y, z coordinates of the arm with the transfer slide. The transfer slide includes a polymer stamp (e.g., a piece of protruded polymer film) that is capable of picking up 2D material flakes exfoliated on the wafer. The polymer stamp can be made with materials such as polycarbonate (PC), polydimethylsiloxane (PDMS), another polymer material, or combination of the materials. Adhesion between the polymer stamp and a 2D material flake at an elevated temperature allows the 2D flakes to be picked-up from the wafer onto the transfer slide. In particular, when the wafer stage is heated to a certain temperate (e.g., ~100° C.), the polymer stamp becomes sticky and can pick up 2D material flakes exfoliated on the wafer. After stacking is performed according to the stack design paradigm, the 2D material stack can stay on the transfer slide until it is transferred to (deposited on) another wafer.

Stepper motors B are configured to control the x, y, θ coordinates of the wafer stage on which the wafer with the exfoliated 2D materials is disposed. Moreover, stepper C controls the z coordinate (e.g., height) of the microscope in order to autofocus the microscope and the camera on the wafer.

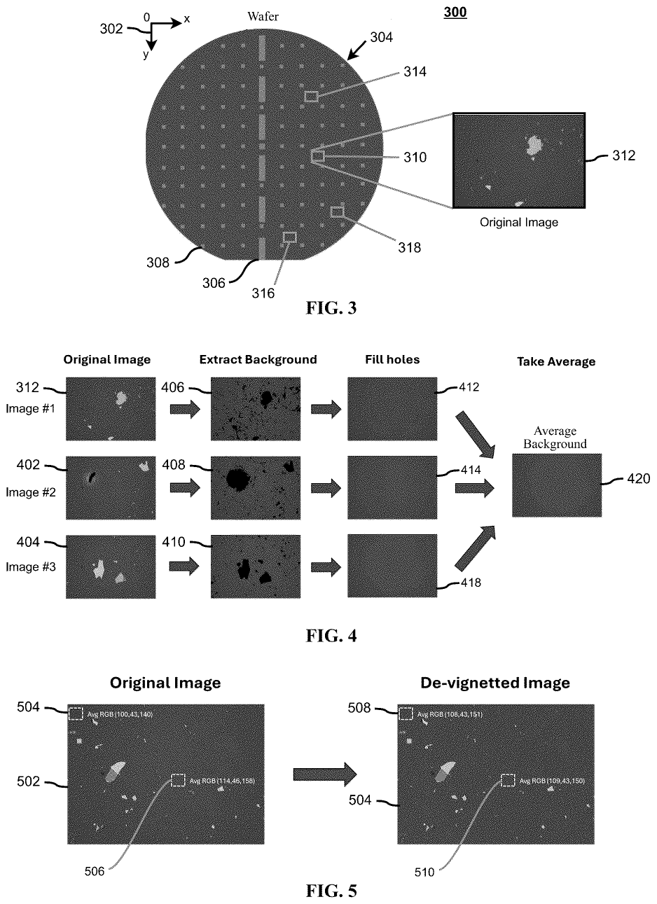

FIGS. 2A and 2B illustrate example graphical user interfaces (GUIs) 200, 208 generated by the material scanning and computing device 104 illustrated in FIG. 1, to automatically scan, catalog, and search 2D material subflakes for automatic stacking according to a stack design paradigm.

FIG. 2A illustrates a GUI 200 that includes buttons 202, 204, and 206, respectively selectable by a user to automatically scan a wafer (illustrated in FIG. 3) having a multiplicity of flakes deposited thereon, automatically analyze images resulting from the scanning to identify subflakes, and make a stack of certain subflakes selected from the wafer according to a result of search of the flake database 108 based on a selected stack design paradigm.

In particular, a user positions and aligns a newly prepared wafer that includes exfoliated flakes in the material scanning and stacking transfer device 102, and selects a button 202 from GUI 200 to scan the wafer.

FIG. 2B illustrates a GUI 208 that is generated material scanning and computing device 104. GUI 208 includes parameters 210-216 that relate to the wafer 300 and flakes exfoliated thereon. In particular, the user can select a wafer thickness 210 (e.g., 285 nm). Typical silicon wafer thicknesses for scanning flakes (such as graphene or other 2D materials) vary based on the required optical contrast and the specific microscopy technique, but are generally 90 nm or 285 nm.

It should be noted that other thicknesses are of course possible based on specific optical contrast and microscopy requirements. The user can further select a left 2D material 212 (e.g., graphene or graphite) and a right 2D material 214 (e.g., hBN) exfoliated on the wafer 300. The 2D material can be selected to be different on the left 212, and/or can be selected to be different on the right 214. Moreover, a user can enter a name 216 to identify the wafer 300, which can be used as a base portion of names for scanned images, as well as name of a flake database generated from the wafer 300.

Upon selections of the wafer and 2D material parameters, a user can select a button 218 to start scanning the wafer for subflakes. FIGS. 3-9 illustrate an example wafer and example scanning of the wafer.

FIG. 3 illustrates an example wafer 300 that includes an example multiplicity of flakes for scanning, cataloging, and stacking using the system illustrated in FIG. 1. In particular, a microscope/camera image is taken every 628 μm×447 μm along an x-y coordinate system 302 that can be centered at a middle of the wafer (e.g., center square indicator 304 along vertical indicator 306 larger than other square indicators 308), resulting in approximately 13,000 original images (e.g., image 312 taken at location 310) that cover the entirety of the wafer 300. It should be noted that original images can be taken of other example locations, such as locations 314, 316, and 318.

It should be noted that the size of the original image 312 in relation to its location 310 is exaggerated in this schematic view. The wafer 300 can be scanned along a zigzag path, or any other selected path. During the operation of scanning, the microscope/camera of the materials scanning and stacking transfer device 102 can be autofocused in relation to the wafer 300 (e.g., every 12 images). Each scanned image is associated with a pair of coordinates (e.g., x-y coordinates) that represent its location on the wafer 300. The name of the wafer (FIG. 2B) coupled with the pair of coordinates can make up constituent parts of the image's file name, for association purposes with the wafer and location on the wafer 300.

The materials scanning and stacking computing device 102 can thus store the original taken images in the flake database 108, for processing as described hereinbelow.

FIGS. 4-7B graphically illustrate example scanning of the wafer to generate a multiplicity of original images saved to the flake database 108, and further processing of the original images to identify flakes and subflakes of the flakes in the original images as illustrated in FIG. 7A for storage as records in the flake database 108 as illustrated in FIGS. 1 and 7B. As described in FIG. 2B, the left of the wafer 300 can be graphene or graphite and the right of the wafer can be BN or hBN. To provide clarity and conciseness, certain locations and associated images of hBN are illustrated on the right side of the wafer 300. It should be noted that the graphene or graphite on the left side of the wafer 300 (or another 2D material) can be processed similarly.

FIG. 4 illustrates processing of several original images (e.g., hBN on the right of the wafer 300), including image 312 of location 310, image 402 of location 314, and image 404 of location 316 to generate an image 420 of a background of the wafer 300 or portion of the wafer 300 having an average background color. The several images that are used can be randomly selected from the entire wafer, or only from that portion of the wafer for which a certain 2D material is processed. While only images 1-3 are shown, it should be noted that a smaller or a larger number of images can be easily used to determine an image with an average background color for the wafer 300.

In an embodiment, original images 312, 402, 404 are randomly selected from the flake database 108. Using canny edge detection, background images 406, 408, 410 are respectively extracted from the original images 312, 402, 404. The background images 406, 408, 410 might include some holes that are caused by flakes, dirt, and/or tape residue resulting from the exfoliation of the 2D material(s). Any holes in the background images 406, 408, 410 are respectively filled as illustrated in filled images 412, 414, 416, by fitting red-green-blue (RGB) values to a cosh-like function. Lastly, the filled images 412, 414, 416 are averaged to be the background image 420 for the wafer 300.

FIG. 5 illustrates de-vignetting the original images saved in the flake database 108, using the background image 420 having an average background color, to generate de-vignetted images. Each of the original images (e.g., the original images 312, 402, 404) saved in the database 106 is de-vignetted to remove optical artifacts at the corners of the images, such that the RGB values of the wafer are approximately the same or similar at a corner(s) versus at a center of each of the images. It should be noted that vignette correction is typically performed on a pixel-by-pixel (or small block basis), applying specific brightness boosts based on a pixel's distance (or a distance of the small block) from the image center. De-vignetting is configured to reverse a darkening effect that can be caused by optical vignetting (e.g., lens characteristics) and pixel vignetting (e.g., sensor angle limitations) of the microscope and the camera included in the material scanning and stacking transfer device 102, as illustrated in FIGS. 1 and 2. For example, individual pixels 504, 506 (or several pixels of each small block of pixels 504, 506) of an original image 502 for a location 318 (FIG. 3) can be de-vignetted to individual pixels 508, 506 (or several pixels of each small block of pixels 504, 506) in a de-vignetted image 504. The de-vignetted images related to the original images can be stored in the flake database 108.

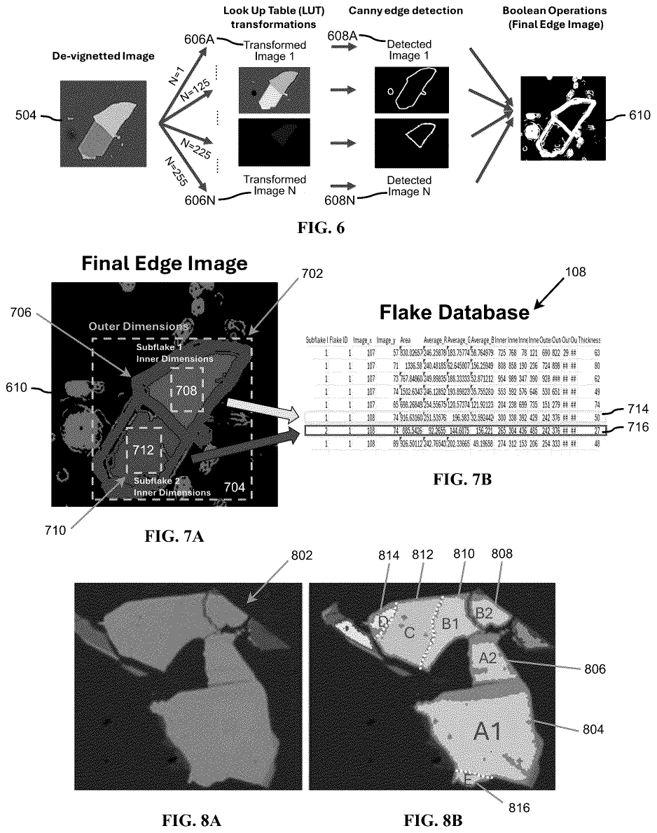

FIG. 6 illustrates an embodiment of generating final edge images based on the de-vignetted images. Each of the de-vignetted images (e.g., image 504) is accessed from the flake database 108 and transformed using Gamma correction function-based Look-Up Table (LUT) for N=1 . . . 255, to a plurality of LUT transformed images 606A . . . 606N. Thereafter, canny edge detection is applied to each of the LUT transformed images 606A-606N to generate canny edge-detected images 608A-608N. A sequence of Boolean operations is applied to the edge-detected images 608A-608N to generate a final edge image 610 for the de-vignetted image 504. The final edge detected image 610 can then be used for identifying the subflakes. The final edge detected images related to the original images can be stored in the flake database 108.

FIGS. 7A and 7B illustrate processing each final edge image 610 to determine a flake 702, its outside dimensions (“OD”) 704, and any connected subflakes 706, 710 in the flake 702 and a respective inner dimension (“ID”) of each of the subflakes 708, 712, as illustrated in FIG. 7A, and then recording flake/subflake related information as records 714, 716 in the flake database 108, as illustrated in FIG. 7B.

Each of the records 714, 716 can include a subflake no. (e.g., indicating one or more subflakes) in a flake, a flake identifier associated with uniquely identifying each flake to which any subflakes relate, x-y location of the flake on the wafer 300, OD of the flake (e.g., x-y values of four outer corners defining an outer dimension of the flake), IDs of any subflakes (e.g., x-y values of four inner corners defining an inner dimension of each subflake), and thickness of each subflake (e.g., derived from an average RGB value inside the ID) of each subflake. It should be noted that each of the final images can be processed similarly to the aforementioned description, resulting in a record being generated in the flake database 108.

FIGS. 8A and 8B illustrate an alternative example embodiment of generating a final edge image based on a de-vignetted image using k-means clustering, in contrast to generating the example final edge image according to LUT transformations and canny edge detection as illustrated in FIG. 6. In an alternative to LUT-based processing, a K-means pixel clustering method can be used in order to detect any subflakes inside a certain flake. In particular, K-means clustering can be effective for detecting and segmenting subflakes of varying thickness within a 2D material flake. It leverages distinct optical contrast values that different layer thicknesses exhibit against the background of the wafer 300 (e.g., SiO₂/Si) in optical microscope images.

In this example, an image of a flake (e.g., hBN) 802 is shown in FIG. 8A. While the flake might have various flakes of different thicknesses, it is not possible for the naked eye to differentiate any subflakes in the flake 802, which might have different thicknesses based on their color contrast in relationship to the background color. However, k-Means pixel clustering can be used to detect the subflakes of this flake using grouping of related colors representing different thicknesses, as particularly illustrated in FIG. 8B, resulting subflakes 808-816 that are part of the flake 802.

In similar fashion to FIGS. 7A and 7B, OD (not shown) of the flake 802 is determined and IDs (not shown) of each of the subflakes 804-816 are also determined, with the resulting information being saved as records that are generated in the database 108, as particularly described hereinabove with reference to FIGS. 7A and 7B.

FIG. 9 is a flowchart 900 of an example method for scanning and analyzing a wafer 300 that includes a multiplicity of exfoliated 2D material flakes. The method starts at operation 902, wherein the wafer 300 including exfoliated 2D material flakes is set forth and aligned on the wafer stage of the material scanning and stacking transfer device 102 as illustrated in FIG. 1B, and a user has selected a scanning operation clicking button 202 on GUI 200 to scan the wafer as illustrated in FIG. 2A.

At operation 904, 2D material flakes that are exfoliated on a SiO₂/Si wafer 300 are scanned in order to generate a plurality of original images. The material scanning and stacking computing device 104 can save these original images in the flake database 108 for further processing by the material scanning and stacking computing device 104, or offloaded to the flake cataloging computing device 106 for further processing.

While in some embodiments, analysis of the original images can be undertaken automatically upon the completion of the scanning, in some other embodiments, the analysis of the images can be undertaken as a result of the user selecting an analyzing operation by clicking button 204 on GUI 200 as illustrated in FIG. 2A. The original images are processed by the material scanning and stacking computing device 104 or the flake cataloging computing device 106 as the case may be by accessing the original images saved in the flake database 108.

At operation 906, there are selected (e.g., randomly) several images (e.g., images 312, 402, 404) from the plurality of original images to determine a background color for the wafer 300. At operation 908, a background of a selected image is extracted, the background might have one or more holes resulting from the scanning, e.g., from flakes, dirt, and/or tape residue (e.g., background images 406, 408, 410). At operation 910, the holes are filled in the extracted background, e.g., fitting RGB values to a cosh-like function (e.g., images 412, 414, 416).

At operation 912, a determination is made as to whether there are more images to be selected for determining the background color. If it is determined at operation 912 that more images are to be selected, the example method 900 iterates operations 908-912 until a desired number of original images are selected for computing the background color of the wafer.

However, if it is determined at operation 912 that no more images are to be selected, the example method 900 continues at operations 914, wherein the filled backgrounds of the selected images (e.g., images 412, 414, 416) are averaged to generate a background image (e.g., background image 420) to be used for processing original images scanned from the wafer 300.

At operation 916, an original image (e.g., original image 502) is de-vignetted utilizing the background image (e.g., background image 420) to generate a de-vignetted image (e.g., de-vignetted image 504). At operation 918, the de-vignetted image is de-blurred to generate a de-blurred and de-vignetted image (not shown). At operation 920, there is performed edge detection using the de-blurred and de-vignetted image to determine plurality of disjoint pieces.

At operation 922, a determination is made as to whether a total area of pieces area of a largest piece<predefined area. If the area remaining is small after the area of largest piece is subtracted, it might mean that the image might have too few flakes and should be eliminated from processing. As an example, it can be considered that there are three (3) pieces found, with a first piece having an area of 15 μm², a second piece having an area of 35 μm², and a third piece having an area of 25 μm². Accordingly, because 75 μm²-35 μm²<400 μm², the image can be discarded as it is considered that there are two few flakes remaining. While the foregoing allows saving of processing time, in some cases, even such images with few flakes can still be processed.

If it is determined at operation 922 that the image includes an insufficient number of flakes (e.g., the total area of pieces minus the area of the largest piece is less than the predefined area), then the present image might be skipped or eliminated, and the method 900 continues at operation 938, as will be described hereinbelow in greater detail.

However, if it is determined at operation 922 that the image includes sufficient number of flakes (e.g., the total area of pieces minus the area of the largest piece is equal to or greater than a predefined area), then the method 900 continues at operation 924 where a flake is identified in the de-blurred and de-vignetted image. At operation 926, a rectangle with outer dimension (OD) that encloses the flake is then determined. At operation 928, a f lake record is generated for the identified flake in the flake database 108.

At operation 930, a determination is made as to whether the identified flake includes any subflakes (e.g., areas of the same flake that have different thicknesses). If it is determined at operation 930 that there are identified subflakes, the method 900 continues at operation 932, where a rectangle with inner dimension (ID) fitting inside each of the subflakes is determined. At operation 934, subflake record associated with the flake record of the flake is generated in the database 108. If it is determined at operation 930 that there are no identified subflakes, then the method continues at operation 936.

At operation 936, a determination is made as to whether there are more flakes to process in the present de-vignetted and de-blurred image. If it is determined at operation 936 that there are more flakes to process, then the method 900 iterates operations 942-936 to process any additional flakes in the present image. If it is determined at operation 936 that there are no more flakes to process, then the method 900 continues at operation 938.

At operation 938, a determination is made as to whether there are more original images to process for the wafer 300. If it is determined at operation 938 that there are more images to process, then the method 900 iterates operations 916-938 to process any additional images for flakes and subflakes. If it is determined at operation 938 that there are no more images to process for the wafer 300, then the method 900 ends at operation 940.

FIGS. 10A and 10B illustrate example graphical user interfaces (GUIs) 200, 208 generated by the material scanning and computing device 104 illustrated in FIG. 1, to automatically scan, catalog, and search 2D material subflakes for automatic stacking according to a stack design paradigm.

FIG. 10A illustrates GUI 200 that includes buttons 202, 204, and 206. As described hereinbefore with reference to FIGS. 2A and 2B, the user instructed via button 202 the material scanning and stacking computing device 104 to the scan a wafer 300 in order to generate a plurality of images, and via button 204 instructed the material scanning and stacking computing device 104 and/or the flake cataloging device 106 to process the plurality of scanned images to generate a flake database 108, including records related to flakes and subflakes exfoliated on the wafer 300.

Moreover, GUI 200 enables a user to select button 208 to make a stack of certain subflakes selected from the wafer 300 according to a result of search of the flake database 108 based on a selected stack design paradigm as illustrated in an example GUI 1000 of FIG. 10B, as further supported by FIGS. 11A-11C.

FIG. 10B illustrates a GUI 1000 that is generated by the material scanning and computing device 104 upon selection of button 208 in GUI 200, assuming that the wafer 300 has been scanned 204 and analyzed 204 for flakes/subflakes as described herein. GUI 1000 includes a stack designer that facilitates selection of stack design paradigm 1002, which then allows input of certain parameters 1004-1014 related to 2D materials that will comprise the heterogenous structure according to the stack design paradigm 1002.

For example, stack design paradigm nos. 2, 3A, or 3B can be selected, as described in greater detail below with reference to FIGS. 11A-11C. Each of the stack design paradigms specifies a spatial relationship between the flakes/subflakes that are to be used in the heterogeneous stack. It should be noted that additional stack design paradigms can be designed and selected in a similar fashion.

In particular, as illustrated in GUI 1000, a stack design paradigm 2 has been selected, which requires two 2D materials to be entered into input area 1010 and a core area entered into input area 1014. For example, the 2D materials according to the stack design paradigm 1002 can be (1) a boron nitride (BN) layer (e.g., hBN) that is defined by an input of a desired thickness 1004 (e.g., 35 nm) and a tolerance value 1006 (e.g., 5 nm) by which the thickness can vary among selected subflakes, and (2) a graphene/graphite (G) layer having a layer count 1008 (e.g., layer count of 2). The core area that is entered into input area 1014 can be defined by a width×length (e.g., 15 μm×20 μm).

Each of the stack design paradigm nos. 3A or 3B requires three 2D materials to be entered into input areas 1010 and 1012, and a core area entered into input area 1014. For example, the 2D materials according to the stack design paradigm 1002 can be (1) a boron nitride layer (e.g., hBN) that is defined by an input of a desired thickness 1004 (e.g., 35 nm) and a tolerance value 1006 (e.g., 5 nm) by which the thickness can vary among selected subflakes, and (2) a graphene/graphite (G) layer having a layer count 1008 (e.g., layer count of 2), and (3) another boron nitride layer (e.g., hBN) that is defined by a desired thickness and a variance value. For example, the stack design paradigms 3A and 3B can (but do not have to) share the same or a similar set of values, with a main difference being that the graphene G (e.g., the second layer in the stack) is positioned to stick out of the topmost layer in the stack design paradigm 3B, while the graphene (G) is fully encapsulated by the two BN layers in stack design paradigm 3A. Accordingly, a difference can be solely a matter of positioning of the flake instead of selection of different flakes. (but do not have to share the same or similar values). As Example: a BN-graphene-BN sandwich can include a top BN layer having an ID of at least 30 μm×30 μm, a thickness of 40 nm~60 nm, a middle Graphene layer having OD at most 25 μm×25 μm, and a thickness of only one atomic layer (monolayer), and a bottom BN layer having an ID of at least 35 μm×30 μm, and a thickness 15 nm~25 nm. The core area that is entered into input area 1014 can be defined by a width and a length (e.g., 15 μm×20 μm).

Upon a selection of the stack design paradigm 1002 and provision of associated layer parameters 1010 and core area parameter 1014, the user can select button submit 1016 to generate an automated stack recommendation for display. In particular, the material scanning and stacking computing device 104, searches the flake database 108 for flakes/subflakes based on entered material and associated parameters (e.g., thickness and core area), and if found, overlays the flakes/subflakes into a recommended stack according to the dictates of the selected stack design paradigm.

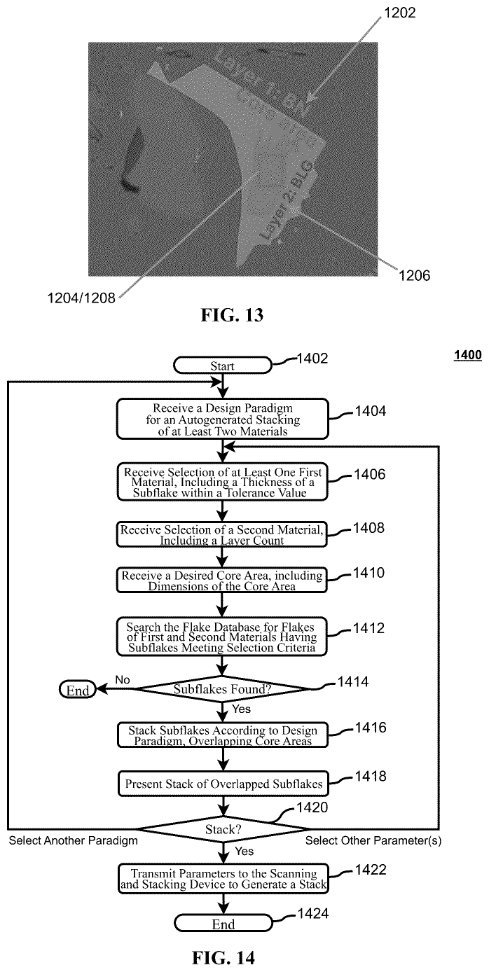

An example stack recommendation is illustrated in FIG. 13, resulting from a combination of an example boron nitride (BN) layer according to parameters 1004, 1006 and an example bilayer graphene (BLG) according to parameter 1008, as respectively illustrated in FIGS. 12A and 12B. If the user is satisfied with the stack recommendation, the stack can be physically generated by the user selecting button 1018, resulting in the material scanning and stacking computing device 104 instructing the material scanning and stacking transfer device 102 to retrieve the 2D materials from the associated location of the wafer 300 and stack the materials as layers according to the selected stack design paradigm 1002.

FIGS. 11A-11C illustrate several example stack design paradigms 2, 3A, and 3B for stacking flakes and/or subflakes. At the beginning of the automated stack recommendation and physical stacking processes, the user initially picks a stack design paradigm that specifies a spatial relationship between the 2D material flakes to be used in generating the stack recommendation.

FIG. 11A illustrates stack design paradigm 2 that includes two layers in which a 2D graphene (G) material flake is designated as layer 2, which is to be disposed on top of a 2D boron nitride (BN) material flake, which is designated as layer 1. As particularly illustrated in FIG. 11A, stack design paradigm 2 requires that outside OD2⊂ID1, in particular that the outside dimension OD2 of G (layer 2—topmost layer) is fully contained within the inside dimension ID1 of BN (layer 1—bottommost layer).

FIG. 11B illustrates stack design paradigm 3A that includes three layers in which (BN) is designated as layer 1, G is designated as layer 2, and another BN is designated as layer 3 (topmost layer). As particularly illustrated in FIG. 11A, stack design paradigm 3A requires that OD2⊂ID1 and OD2⊂ID3, in particular that the outside dimension OD2 of G (layer 2—middle layer) is fully contained within the inside dimension ID1 of BN (layer 1—bottommost layer), and further that the outside dimension OD2 of G (layer 2—middle layer) is fully contained within the inside dimension ID3 (layer 3—topmost layer).

FIG. 11C illustrates stack design paradigm 3B that also includes three layers in which (BN) is designated as layer 1, G is designated as layer 2, and BN is designated as layer 3 (topmost layer). As particularly illustrated in FIG. 11A, in stack design paradigm 3A a part of the graphene layer 2 is not covered by the BN of layer 3. Specifically, stack design paradigm 3A requires that OD2⊂ID1 and ID2 [symbol] OD3 and ID2∩ID3≠∅, in particular that the outside dimension OD2 of G (layer 2—middle layer) is fully contained within the inside dimension ID1 of BN (layer 1—bottommost layer) and inside dimension ID2 of G (layer 2—middle layer) is not fully contained in the outside dimension OD3 of BN (layer 3—topmost layer), and further that inside dimension ID2 (layer 2—middle layer) is at least partially in inside dimension ID3 (layer 3—topmost layer).

It should be noted that although one or more alternative conditions may also satisfy a stack design paradigm for certain specific flake geometries, very strong conditions are set forth herein based on the relationships of IDs and ODs of 2D material flakes, so as to not only minimize computational complexity but also completely achieve set requirements.

FIGS. 12A and 12B illustrate example flakes and/or subflakes 1202, 1206 selected from the flake database 108 illustrated in FIG. 1, based on a selected stack design paradigm 1002 and a plurality of selected parameters 1004-1008 and 1014 related to the flakes and/or subflakes.

In particular, the user chose a stack design paradigm 2 as illustrated in FIGS. 10B and 11A, with a boron nitride BN as layer 1 having a thickness of 35 nm within a tolerance±5 nm a bilayer graphene BLG as layer 2, and a core area (15 μm×20 μm) representing a minimum area over which layers 1 and 2 in the stack must coincide.

Upon selection of submit button 1016, the material scanning and stacking computing device 104 performs a search of the flake database 108 using the information entered, as illustrated in FIG. 10B. The search results in a BN subflake 1202 as layer 1, with a thickness of 36 nm that satisfies 35 nm±5 nm requirement and inner dimension ID1 that is larger than the core area 1204, as illustrated in FIG. 12A. Moreover, the search further results in a BLG flake 1206 as layer 2, with an inner dimension ID2 that is bigger than core area 1208, and whose outer dimension OD2 can be contained in the ID1 of the BN subflake 1202, as illustrated in FIG. 12B.

After finding flakes 1202, 1206, the material scanning and stacking computing device 104 generates a stack recommendation image by overlaying the two flake images, as described hereinbelow in relation to FIG. 13.

FIG. 13 illustrates an example automated stacking recommendation image that overlays two flake images 1202, 1206 that are found in the flake database 108 based on a required stack design paradigm 1002, as well as thickness and core area parameters 1010, 1014. In particular, BLG 1206 (layer 2) is completely disposed on the BN 1202 (layer 1), and BLG and BN respective core areas 1204, 1208 cover the required core area 1014. The core area 1204 of BN subflake 1202 and core area 1208 of BLG flake 1206 are accordingly at least the required 15 μm×20 μm, and are overlapped as particularly illustrated in FIG. 13.

More specifically, the example stack recommendation thus results from a combination of the example boron nitride (BN—layer 2) layer according to parameters 1004, 1006 and an example bilayer graphene (BLG—layer 1) according to parameter 1008, and their overlapping core areas 1204, 1208, as particularly illustrated in FIG. 13. If the user is satisfied with the stack recommendation, the stack design can be physically generated by the user by selecting stack button 1018, resulting in the material scanning and stacking computing device 104 instructing the material scanning and stacking transfer device 102 to retrieve the 2D materials from the associated locations of the wafer 300 and stack the materials as layers according to the selected stack design paradigm 1002, wherein the BLG layer 1206 is disposed atop the BN layer 1204, with their respective core areas 1204, 1208 overlapping.

FIG. 14 is an example is a flowchart 1400 of an example method of generating a stack recommendation of flakes resulting from a search of the flake database 108, and stacking a heterogeneous stack of 2D materials from the wafer 300 that includes a multiplicity of exfoliated 2D material flakes, according to a stack design paradigm and parameters associated with the 2D materials.

The example method 1400 starts at operation 1402, wherein the user has clicked button 208 on the GUI 200 to make a stack as illustrated in FIG. 10A and GUI 1000 has been presented to the user to enter parameters of the 2D materials for the stack as illustrated in FIG. 10B.

At operation 1404, a stack design paradigm is received for an autogenerated stack of at least two 2D materials. For example, stack design paradigm 2 is selected at stack design paradigm input 1002 from among several stack design paradigms, as illustrated in FIGS. 11A-11C.

At operation 1406, a selection of at least one first material is received, including parameters for a thickness of a subflake within a tolerance value. For example, there is selected a BN material having a thickness 1004 nm within a tolerance value 1006 (i.e., 35 nm±5 nm), as particularly illustrated in FIG. 10B.

At operation 1408, a selection of a second material is received, including a parameter for a layer count. For example, there is selected a graphene material having a layer count of two (e.g., bilayer graphene-BLG), as particularly illustrated in FIG. 10B.

At operation 1410, a parameter for a desired core area is received. For example, there is selected a core area 1014 (e.g., 15 μm×20 μm), as particularly illustrated in FIG. 10B.

At operation 1412, the flake database 108 is searched for flakes of first 2D material and the second 2D second material, including possible subflakes meeting selection criteria. For example, upon selection button submit 1016, the material scanning and stacking computing device 104 searches the flake database 108 for flakes/subflakes based on entered materials and associated parameters (e.g., thickness and core area).

At operation 1414, a determination is made as to whether flakes/subflakes are found matching the entered materials and the associated parameters. If it is determined at operation 1414 that desired flakes/subflakes are not found, then a warning message can be presented to the user and the method 1400 then ends at operation 1424.

However, if it is determined at operation 1414 that desired flakes/subflakes are found, then the method continues at operation 1416, where flakes/subflakes are stacked according to the stack design paradigm, overlapping their core areas. For example, BN 1202 and BLG 1206 flakes/subflakes are found as a result of a search in the flake database 108, as respectively illustrated in FIGS. 12A and 12B.

At operation 1418, the stack as overlapped is presented as a recommendation to the user for review and possible physical stacking. For example, an autogenerated stack recommendation of a stack of BN 1202 and BLG 1206 with respective overlapped core areas 1204, 1206 is illustrated in FIG. 13.

At operation 1420, a determination is made as to whether a physical stack is to be generated in accordance. If it is determined at operation 1420 that the method 1400 should proceed with stacking, then the method proceeds at operation 1422, where the stack design paradigm and the parameters are transmitted to the material scanning and stacking transfer device to generate a physical stack (not shown) according to the selected stack design paradigm and the selected parameters.

If it is determined at operation 1420 that another stack design paradigm is to be selected, then the method 1400 proceeds with iterating operations 1404-1420 for another stack design paradigm. However, if it is determined at operation 1420 that other parameters are to be selected for the current stack design paradigm, then the method 1400 proceeds with iterating operations 1406-1420.

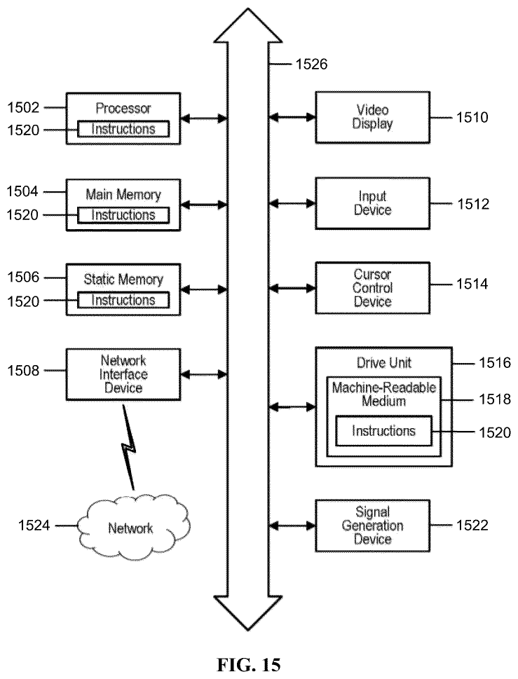

FIG. 15 is a block diagram of an illustrative embodiment of a general computer system 1500. The computer system 1500 can include a set of instructions that can be executed to cause the computer system 1500 to perform any one or more of the methods or computer based functions disclosed herein in FIGS. 1-14. The computer system 1500, or any portion thereof, may operate as a standalone device or may be connected, e.g., using a network or other connection, to other computer systems or peripheral devices. For example, the computer system 1500 may be any one of the electronic components 102-108, or integrated into one of the electronic components 102-108 in the example system 100, as illustrated in FIG. 1.

The computer system 1500 may also be implemented as or incorporated into various devices, such as a personal computer (PC), a tablet PC, a personal digital assistant (PDA), a computing device or mobile device (e.g., smartphone), a palmtop computer, a laptop computer, a desktop computer, a communications device, a control system, a web appliance, a computer-enabled microscope/camera, or any other machine capable of executing a set of instructions (sequentially or otherwise) that specify actions to be taken by that machine. Further, while a single computer system 1500 is illustrated, the term “system” shall also be taken to include any collection of systems or sub-systems that individually or jointly execute a set, or multiple sets, of instructions to perform one or more computer functions.

As illustrated in FIG. 15, the computer system 1500 may include a processor 1502, e.g., a central processing unit (CPU), a graphics-processing unit (GPU), or both. Moreover, the computer system 1500 may include a main memory 1504 and a static memory 1506 that can communicate with each other via a bus 1526. As shown, the computer system 1500 may further include a video display unit 1510, such as a liquid crystal display (LCD), an organic light emitting diode (OLED), a flat panel display, a solid state display, a cathode ray tube (CRT), or another video display unit. Additionally, the computer system 1500 may include an input device 1512, such as a keyboard, and a cursor control device 1514, such as a mouse. The computer system 1500 can also include a disk drive (or solid state) unit 1516, a signal generation device 1522, such as a speaker or remote control, and a network interface device 1508.

In a particular embodiment or aspect, as depicted in FIG. 15, the disk drive (or solid state) unit 1516 may include a computer-readable medium 1518 in which one or more sets of instructions 1520, e.g., software, can be embedded. Further, the instructions 1520 may embody one or more of the methods or logic as described herein. In a particular embodiment or aspect, the instructions 1520 may reside completely, or at least partially, within the main memory 1504, the static memory 1506, and/or within the processor 1502 during execution by the computer system 1500. The main memory 1504 and the processor 1002 also may include computer-readable media.

In an alternative embodiment or aspect, dedicated hardware implementations, such as application specific integrated circuits, programmable logic arrays, and/or other hardware devices, can be constructed to implement one or more of the methods described herein. Applications that may include the apparatus and systems of various embodiments or aspects can broadly include a variety of electronic and computer systems. One or more embodiments or aspects described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments or aspects, the methods described herein may be implemented by software programs tangibly embodied in a processor-readable medium and may be executed by a processor. Further, in an exemplary, non-limited embodiment or aspect, implementations can include distributed processing, component/object distributed processing, and parallel processing. Alternatively, virtual computer system processing can be constructed to implement one or more of the methods or functionality as described herein.

It is also contemplated that a computer-readable medium includes instructions 1520 or receives and executes instructions 1520 responsive to a propagated signal, so that a device connected to a network 1524 can communicate voice, video or data over the network 1524. Further, the instructions 1520 may be transmitted or received over the network 1524 via the network interface device 1508.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, example embodiment or aspect, the computer-readable medium can include a solid-state memory, such as a memory card or other package, which houses one or more non-volatile read-only memories. Further, the computer-readable medium can be a random access memory or other volatile re-writable memory. Additionally, the computer-readable medium can include a magneto-optical or optical medium, such as a disk or tapes or other storage device to capture carrier wave signals, such as a signal communicated over a transmission medium. A digital file attachment to an e-mail or other self-contained information archive or set of archives may be considered a distribution medium that is equivalent to a tangible storage medium. Accordingly, any one or more of a computer-readable medium or a distribution medium and other equivalents and successor media, in which data or instructions may be stored, are included herein.

In accordance with various embodiments or aspects, the methods described herein may be implemented as one or more software programs running on a computer processor. Dedicated hardware implementations including, but not limited to, application specific integrated circuits, programmable logic arrays, and other hardware devices can likewise be constructed to implement the methods described herein. Furthermore, alternative software implementations including, but not limited to, distributed processing or component/object distributed processing, parallel processing, or virtual machine processing can also be constructed to implement the methods described herein.

It should also be noted that software that implements the disclosed methods may optionally be stored on a tangible storage medium, such as: a magnetic medium, such as a disk or tape; a magneto-optical or optical medium, such as a disk; or a solid state medium, such as a memory card or other package that houses one or more read-only (non-volatile) memories, random access memories, or other re-writable (volatile) memories. The software may also utilize a signal containing computer instructions. A digital file attachment to e-mail or other self-contained information archive or set of archives is considered a distribution medium equivalent to a tangible storage medium. Accordingly, a tangible storage medium or distribution medium as listed herein, and other equivalents and successor media, in which the software implementations herein may be stored, are included herein.

There have thus been described system and method of automatically cataloging and searching 2D material subflakes for automatic stacking according to a stack design paradigm. Although specific example embodiments or aspects have been described, it will be evident that various modifications and changes may be made to these embodiments or aspects without departing from the broader scope of the invention. Accordingly, the specification and drawings are to be regarded in an illustrative rather than a restrictive sense. The accompanying drawings that form a part hereof, show by way of illustration, and not of limitation, specific embodiments or aspects in which the subject matter may be practiced. The embodiments or aspects illustrated are described in sufficient detail to enable those skilled in the art to practice the teachings disclosed herein. Other embodiments or aspects may be utilized and derived therefrom, such that structural and logical substitutions and changes may be made without departing from the scope of this disclosure. This Detailed Description, therefore, is not to be taken in a limiting sense, and the scope of various embodiments or aspects is defined only by the appended claims, along with the full range of equivalents to which such claims are entitled.

Such embodiments or aspects of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments or aspects have been illustrated and described herein, it should be appreciated that any arrangement calculated to achieve the same purpose may be substituted for the specific embodiments or aspects shown. This disclosure is intended to cover any and all adaptations or variations of various embodiments or aspects. Combinations of the above embodiments or aspects, and other embodiments or aspects not specifically described herein, will be apparent to those of skill in the art upon reviewing the above description.

The Abstract is provided to comply with 37 CFR § 1.72(b) and will allow the reader to quickly ascertain the nature and gist of the technical disclosure. It is submitted with the understanding that it will not be used to interpret or limit the scope or meaning of the claims.

In the foregoing description of the embodiments or aspects, various features are grouped together in a single embodiment for the purpose of streamlining the disclosure. This method of disclosure is not to be interpreted as reflecting that the claimed embodiments or aspects have more features than are expressly recited in each claim. Rather, as the following claims reflect, inventive subject matter lies in less than all features of a single disclosed embodiment or aspect. Thus, the following claims are hereby incorporated into the Detailed Description, with each claim standing on its own as a separate example embodiment or aspect. It is contemplated that various embodiments or aspects described herein can be combined or grouped in different combinations that are not expressly noted in the Detailed Description. Moreover, it is further contemplated that claims covering such different combinations can similarly stand on their own as separate example embodiments or aspects, which can be incorporated into the Detailed Description.

1. A system of stacking two-dimensional (2D) crystal materials, the system comprising:
a processing device;
a memory storing instructions that, when executed by the processing device, perform operations comprising:
receiving a stack design paradigm specifying a spatial relationship between at least two selected 2D crystal materials, a thickness parameter for each of the 2D crystal materials, and a core area for each of the 2D crystal materials;
searching a flake database for images of subflakes related to the selected 2D crystal materials that meet the thickness and the core area for each of the 2D materials;
generating a recommendation of a heterogeneous stack of images of the subflakes according to the spatial relationship, overlapping core areas of the subflakes; and
presenting the heterogenous stack.

2. The system according to claim 1, wherein the operations comprise instructing a scanning and stacking transfer device to physically generate the heterogenous stack by retrieving and stacking the subflakes of the images, exfoliated on a wafer according to the stack design paradigm.

3. The system according to claim 1, wherein the operations comprise determining an inner dimension (ID1) of a first subflake and an outer dimension (OD2) of a second subflake, such that OD2⊂ID1.

4. The system according to claim 1, wherein the operations comprise determining an inner dimension (ID1) of a first subflake, an outer dimension (OD2) of a second subflake, and an inner dimension (ID3) of a third flake, such that OD2⊂ID1 and OD2⊂ID3.

5. The system according to claim 1, wherein the operations comprise determining an inner dimension (ID1) of a first subflake, an inner dimension (ID2) and outer dimension (OD2) of a second subflake, and an inner dimension (ID3) and an outer dimension (OD3) of a third flake, such that OD2⊂ID1 and ID2 [symbol] OD3 and ID2∩ID3≠∅.

6. The system according to claim 1, wherein the at least two selected 2D crystal materials include at least boron nitride, and graphene or graphite.

7. The system according to claim 6, wherein boron nitride is hexagonal boron nitride (hBN).

8. The system according to claim 1, wherein the operations comprise generating a record in the flake database for each of the subflakes.

9. The system according to claim 1, wherein operations of generating a record in the flake database for each of the subflakes comprises:
scanning a plurality images of flakes exfoliated at locations of a wafer;
generating an edge image for each of the flakes;
determining an outer dimension (OD) of each of the flakes;
identifying one or more subflakes of each of the flakes;
determining an inner dimension (ID) of each of the subflakes;
computing an average thickness of each of the subflakes; and
saving a record comprising a subflake identifier, a flake identifier, location of the flake exfoliated on the wafer, OD of the flake, ID of the subflake, and the average thickness of the subflake.

10. The system according to claim 9, wherein the operations of generating a record in the flake database for each of the subflakes further comprises:
determining an average background image for at least a portion of the wafer using several random images of the plurality of images scanned from the wafer;
de-vignetting the plurality images based on the average background image; and
generating the edge image for each of the flakes based on one of look-up table transformations coupled with canny edge detection, or k-clustering.

11. A method of stacking two-dimensional (2D) crystal materials, the method comprising:
receiving a stack design paradigm specifying a spatial relationship between at least two selected 2D crystal materials, a thickness parameter for each of the 2D crystal materials, and a core area for each of the 2D crystal materials;
searching a flake database for images of subflakes related to the selected 2D crystal materials that meet the thickness and the core area for each of the 2D materials;
generating a recommendation of a heterogeneous stack of images of the subflakes according to the spatial relationship, overlapping core areas of the subflakes; and
presenting the heterogenous stack.

12. The method according to claim 11, wherein the method comprises instructing a scanning and stacking transfer device to physically generate the heterogenous stack by retrieving and stacking the subflakes of the images, exfoliated on a wafer according to the stack design paradigm.

13. The method according to claim 11, wherein the method comprises determining an inner dimension (ID1) of a first subflake and an outer dimension (OD2) of a second subflake, such that OD2⊂ID1.

14. The method according to claim 11, wherein the method comprises determining an inner dimension (ID1) of a first subflake, an outer dimension (OD2) of a second subflake, and an inner dimension (ID3) of a third flake, such that OD2⊂ID1 and OD2⊂ID3.

15. The method according to claim 11, wherein the method comprises determining an inner dimension (ID1) of a first subflake, an inner dimension (ID2) and outer dimension (OD2) of a second subflake, and an inner dimension (ID3) and an outer dimension (OD3) of a third flake, such that OD2⊂ID1 and ID2 [symbol] OD3 and ID2∩ID3≠∅.

16. The method according to claim 11, wherein the at least two selected 2D crystal materials include at least boron nitride, and graphene or graphite.

17. The method according to claim 16, wherein boron nitride is hexagonal boron nitride (hBN).

18. The method according to claim 11, wherein the method comprises generating a record in the flake database for each of the subflakes.

19. The method according to claim 11, wherein generating the record in the flake database for each of the subflakes comprises:
scanning a plurality images of flakes exfoliated at locations of a wafer;
generating an edge image for each of the flakes;
determining an outer dimension (OD) of each of the flakes;
identifying one or more subflakes of each of the flakes;
determining an inner dimension (ID) of each of the subflakes;
computing an average thickness of each of the subflakes; and
saving a record comprising a subflake identifier, a flake identifier, location of the flake exfoliated on the wafer, OD of the flake, ID of the subflake, and the average thickness of the subflake.

20. The method according to claim 19, wherein generating the record in the flake database for each of the subflakes further comprises:
determining an average background image for at least a portion of the wafer using several random images of the plurality of images scanned from the wafer;
de-vignetting the plurality images based on the average background image; and
generating the edge image for each of the flakes based on one of look-up table transformations coupled with canny edge detection, or k-clustering.
